(19) United States
(12) Patent Application Publication
(10) Pub. No.: US 2025/0081473 A1
(43) Pub. Date: Mar. 6, 2025

(54) SEMICONDUCTOR DEVICE

(71) Applicant: Kioxia Corporation, Tokyo (JP)

(72) Inventor: Keiichi NIWA, Yokkaichi Mie (JP)

(73) Assignee: Kioxia Corporation, Tokyo (JP)

(21) Appl. No.: 18/808,270

(22) Filed: Aug. 19, 2024

(30) Foreign Application Priority Data
Aug. 29, 2023 (JP) 2023-139334

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2225/06541; H01L 2225/06548; H01L 2225/06572; H01L 2225/06586; H01L 2924/1431; H01L 2924/1434

(57) ABSTRACT

A semiconductor device includes a plurality of semiconductor chips stacked on top of one another. Each of the plurality of semiconductor chips includes a first upper face on which a first pad and a first insulating film enclosing the first pad are formed, a first lower face on which a second pad is formed, and at least one first side face, connected to the first insulating film in an end portion of the first upper face, on which a second insulating film is formed, the second insulating film and the second insulating film having the same composition, and the second pad of an upper one of the semiconductor chips and the first pad of a lower one of the semiconductor chips are connected.

### CROSS-REFERENCE TO RELATED APPLICATION(S)

This application is based upon and claims the benefit of priority from Japanese Patent Application No. 2023-139334, filed Aug. 29, 2023, the entire contents of which are incorporated herein by reference.

### FIELD

Embodiments described herein relate generally to a semiconductor device.

### BACKGROUND

Among semiconductor devices, there are semiconductor devices such that a semiconductor element is sealed using a molded resin.

For example, when adhesion between a molded resin and a semiconductor element is not good, the molded resin may become detached from the semiconductor element.

### DESCRIPTION OF THE DRAWINGS

FIG. 1 is a sectional schematic view illustrating an example of a structure of a storage device according to a first embodiment, and is a sectional view parallel to an XY plane.

FIG. 2 is a sectional schematic view illustrating an example of a structure of a semiconductor chip according to the first embodiment, and is a sectional view parallel to the XY plane.

FIG. 3 is a drawing in which an upper portion of a layered body shown in FIG. 1 is enlarged.

FIG. 4 is a schematic view showing a process of manufacturing a semiconductor device according to the first embodiment.

FIG. 5 is a schematic view showing a process of manufacturing the semiconductor device according to the first embodiment.

FIG. 6 is a schematic view showing a process of manufacturing the semiconductor device according to the first embodiment.

FIG. 7 is a schematic view showing a process of manufacturing the semiconductor device according to the first embodiment.

FIG. 8 is a schematic view showing a process of manufacturing the semiconductor device according to the first embodiment.

FIG. 9 is a schematic view showing a process of manufacturing the semiconductor device according to the first embodiment.

FIG. 10 is a schematic view showing a process of manufacturing the semiconductor device according to the first embodiment.

FIG. 11 is a schematic view showing a process of manufacturing the semiconductor device according to the first embodiment.

FIG. 12 is a schematic view showing a process of manufacturing the semiconductor device according to the first embodiment.

FIG. 13 is a schematic view showing a process of manufacturing the semiconductor device according to the first embodiment.

FIG. 14 is a schematic view showing a process of manufacturing the semiconductor device according to the first embodiment.

FIG. 15 is a schematic view showing a process of manufacturing the semiconductor device according to the first embodiment.

FIG. 16 is a schematic view showing a process of manufacturing the semiconductor device according to the first embodiment.

FIG. 17 is a schematic view showing a process of manufacturing the semiconductor device according to the first embodiment.

FIG. 18 is a drawing in which an upper portion of a layered body according to a second embodiment is enlarged.

FIG. 19 is a sectional schematic view illustrating an example of a structure of a semiconductor chip according to the second embodiment, and is a sectional view parallel to the XY plane.

FIG. 20 is a sectional schematic view illustrating an example of a structure of a storage device according to a third embodiment, and is a sectional view parallel to the XY plane.

FIG. 21 is an enlargement of a portion of FIG. 3 enclosed by dotted lines.

### DETAILED DESCRIPTION

Embodiments provide a semiconductor device such that

resin can be restricted from becoming detached from a semiconductor chip.

In general, according to one embodiment, a semiconductor device includes a plurality of semiconductor chips stacked on top of one another. Each of the plurality of semiconductor chips includes a first upper face on which a first pad and a first insulating film enclosing the first pad are formed, a first lower face on which a second pad is formed, and at least one first side face, connected to the first insulating film in an end portion of the first upper face, on which a second insulating film is formed, the second insulating film and the second insulating film having the same composition, and the second pad of an upper one of the semiconductor chips and the first pad of a lower one of the semiconductor chips are connected.

Hereafter, embodiments will be described while referring to the attached drawings. In order to facilitate understanding of the description, the same reference signs will be applied as far as possible to identical components in the drawings, and redundant descriptions will be omitted.

An X axis, a Y axis, and a Z axis may be shown in the drawings. The X axis, the Y axis, and the Z axis form right-handed three-dimensional Cartesian coordinates. Hereafter, an X axis arrow direction may be called an X axis + direction, and a direction opposite to that of the arrow an X axis− direction, with the same applying to the other axes. The Z axis + direction and the Z axis − direction may be called “upward” and “downward” respectively. Also, planes perpendicular to the X axis, the Y axis, and the Z axis may be called a YZ plane, a ZX plane, and an XY plane respectively. Also, the Z axis direction may be called an “up-down direction”. “Upward”, “downward”, and “up-down direction” are merely terms indicating a relative positional relationship in the drawings, and are not terms that specify an orientation having a vertical direction as a reference.

Also, unless specifically stated otherwise, dimensions and the like of components shown in the drawings are for facilitating understanding of the description, and may be shown differing from actual dimensions.

In the present specification, “connection” includes not only a physical connection but also an electrical connection, and unless specifically stated otherwise, includes not only a direct connection but also an indirect connection via another object.

In the present specification, unless specifically stated otherwise, “formed upward” includes not only a case of being formed in contact upward, but also a case of being formed upward across another object. The same applies to a case of being “formed downward”, or the like.

### First Embodiment

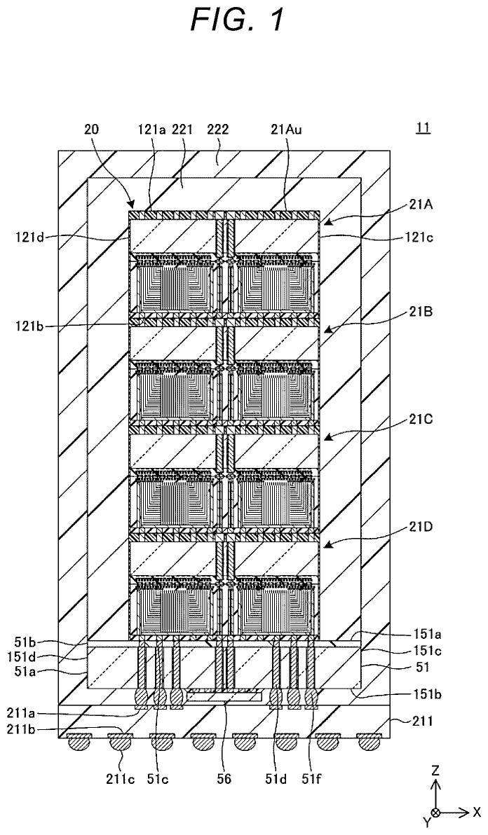

Hereafter, a configuration of a storage device 11 (one example of a “semiconductor device”) according to a first embodiment will be described. FIG. 1 is a sectional schematic view illustrating an example of a structure of a storage device according to the first embodiment, and is a sectional view parallel to the XY plane.

As shown in FIG. 1, the storage device 11 includes a layered body 20, an interposer chip 51, a controller chip 56, an organic substrate 211, and sealing resins 221 and 222.

The layered body 20 includes semiconductor chips 21A, 21B, 21C, and 21D stacked in the up-down direction. Hereafter, each of the semiconductor chips 21A, 21B, 21C, and 21D may be called a semiconductor chip 21. Also, although a configuration such that the layered body 20 includes four semiconductor chips 21 will be described, this is not limiting. The layered body 20 may be of a configuration including two, three, or five or more semiconductor chips 21.

The interposer chip 51 includes a semiconductor layer 51a, an insulating layer 51b, and a solder ball 51f. Hereafter, an upper face, a lower face, an X axis + direction face, and an X axis − direction face of the interposer chip 51 may be called an upper face 151a, a lower face 151b, a side face 151c, and a side face 151d. Also, each of the side faces 151c and 151d may be called a side face 151.

The semiconductor layer 51a is a semiconductor including, for example, silicon. The semiconductor layer 51a is electrically connected downward to the solder ball 51f, and includes a via 51d penetrating in the up-down direction. The insulating layer 51b is provided above the semiconductor layer 51a, and includes a pad 51c that is electrically connected to the via 51d.

The lowermost semiconductor chip 21D of the layered body 20 is bonded to the upper face 151a of the interposer chip 51. The controller chip 56 is mounted face down on the lower face 151b of the interposer chip 51.

Above the interposer chip 51, the layered body 20 is covered by the sealing resin 221. The sealing resin 221 includes, for example, an epoxy resin and a filler.

The organic substrate 211 includes pads 211a and 211b and a solder ball 211c. The pads 211a and 211b are provided exposed in an upper face and a lower face respectively of the organic substrate 211. The solder ball 211c is connected to the pad 211b.

The interposer chip 51 is flip-chip connected to the organic substrate 211 by the solder ball 51f being connected to the pad 211a of the organic substrate 211.

Above the organic substrate 211, the interposer chip 51 and the sealing resin 221 are covered by the sealing resin 222. The sealing resin 222 includes, for example, an epoxy resin and a filler.

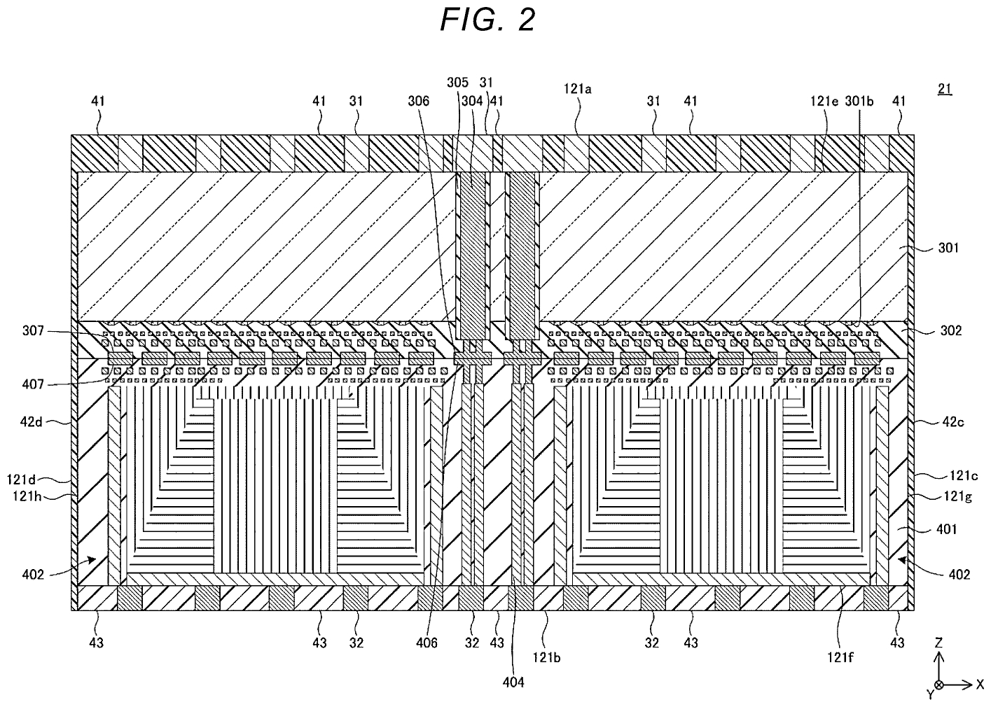

FIG. 2 is a sectional schematic view illustrating an example of a structure of a semiconductor chip according to the first embodiment, and is a sectional view parallel to the XY plane. As shown in FIG. 2, the semiconductor chip 21 includes an upper face 121a (an example of a “first upper face”), a lower face 121b (an example of a “first lower face”), and side faces 121c and 121d. Hereafter, each of the side faces 121c and 121d may be called a side face 121.

The side faces 121c and 121d are faces approximately parallel to the YZ plane, and are positioned in the X axis + direction and the X axis − direction respectively. Although not shown, the semiconductor chip 21 further includes two side faces that are positioned one each in the Y axis + direction and the Y axis − direction, and are approximately parallel to the ZX plane. Hereafter, the side faces 121c and 121d will be described as representatives, but the two side faces approximately parallel to the ZX plane also have the same configuration as the side faces 121c and 121d.

The upper face 121a is a face approximately parallel to the XY plane, on which a pad 31 (one example of a “first pad”) and an insulating film 41 (one example of a “first insulating film”) enclosing the pad 31 are formed. The lower face 121b is a face approximately parallel to the XY plane, on which a pad 32 (one example of a “second pad”) and an insulating film 43 (one example of a “third insulating film”) enclosing the pad 32 are formed.

An insulating film 42c (one example of a “second insulating film”) is formed on the side face 121c. The insulating film 42c is connected to the insulating films 41 and 43 in an end portion of the upper face 121a and an end portion of the lower face 121b respectively, and has a composition the same as that of the insulating film 41.

In the same way, an insulating film 42d (one example of a “second insulating film”), which is connected to the insulating films 41 and 43 in an end portion of the upper face 121a and an end portion of the lower face 121b respectively and has a composition the same as that of the insulating film 41, is formed on the side face 121d. Hereafter, each of the insulating films 42c and 42d may be called an insulating film 42. In the present embodiment, the insulating films 41 and 42 are formed integrated.

The insulating film 43 has the same composition as that of the insulating films 41 and 42. In the present embodiment, the insulating films 41, 42, and 43 are formed of a resin including a polymer. Specifically, the insulating films 41, 42, and 43 are formed of a resin including a polyimide.

Hereafter, the semiconductor chip 21 will be described in detail. The semiconductor chip 21 further includes a substrate 301, an insulating layer 302, and an insulating layer 401.

The substrate 301 is, for example, a semiconductor substrate including silicon. An upper face of the substrate 301 is a face approximately parallel to the XY plane, and forms a face of a base of the insulating film 41 (hereafter, may be called a base face 121e). The pad 31 and the insulating film 41 are provided on the base face 121e. A circuit, for example, is formed on a lower face 301b of the substrate 301.

The insulating layer 302 is provided on the face 301b, and includes pads 306 and 307. The pads 306 and 307 are exposed in a lower face of the insulating layer 302. The pads 306 and 307 are, for example, electrically connected to the circuit formed on the face 301b.

The insulating layer 401 is provided on the lower face of the insulating layer 302, and includes a memory array 402, a plug 404, and pads 406 and 407. A lower face of the insulating layer 401 is a face approximately parallel to the XY plane, and forms a face of a base of the insulating film 43 (hereafter, may be called a base face 121f). The pad 32 and the insulating film 43 are provided on the base face 121f. The pads 406 and 407, which are joined to the pads 306 and 307 respectively, are formed on an upper face of the insulating layer 401. The pads 306 and 307 are, for example, electrically connected to the memory array 402.

A through via 304 is provided across the insulating layer 305 in the substrate 301 and the insulating layer 302. The through via 304 is a through-silicon via (TSV) that extends in the up-down direction and penetrates the substrate 301. The through via 304 electrically connects the pad 31 and the pad 306.

The plug 404 is metal wiring that extends in the up-down direction and penetrates the insulating layer 401. The plug 404 electrically connects the pad 32 and the pad 406.

Faces in the X axis +direction of each of the substrate 301, the insulating layer 302, and the insulating layer 401 are faces that are integrated and flat (hereafter, may be called a base face 121g). The insulating film 42c is formed on the base face 121g.

In the same way, faces in the X axis-direction of each of the substrate 301, the insulating layer 302, and the insulating layer 401 are faces that are integrated and flat (hereafter, may be called a base face 121h). The insulating film 42d is formed on the base face 121h.

Although not shown, the semiconductor chip 21 further includes two base faces that are positioned one each in the Y axis + direction and the Y axis − direction, and are approximately parallel to the ZX plane. In the present embodiment, the base faces 121g and 121h will be described as representatives, but the two base faces that are approximately parallel to the ZX plane also have the same configuration as the base faces 121g and 121h.

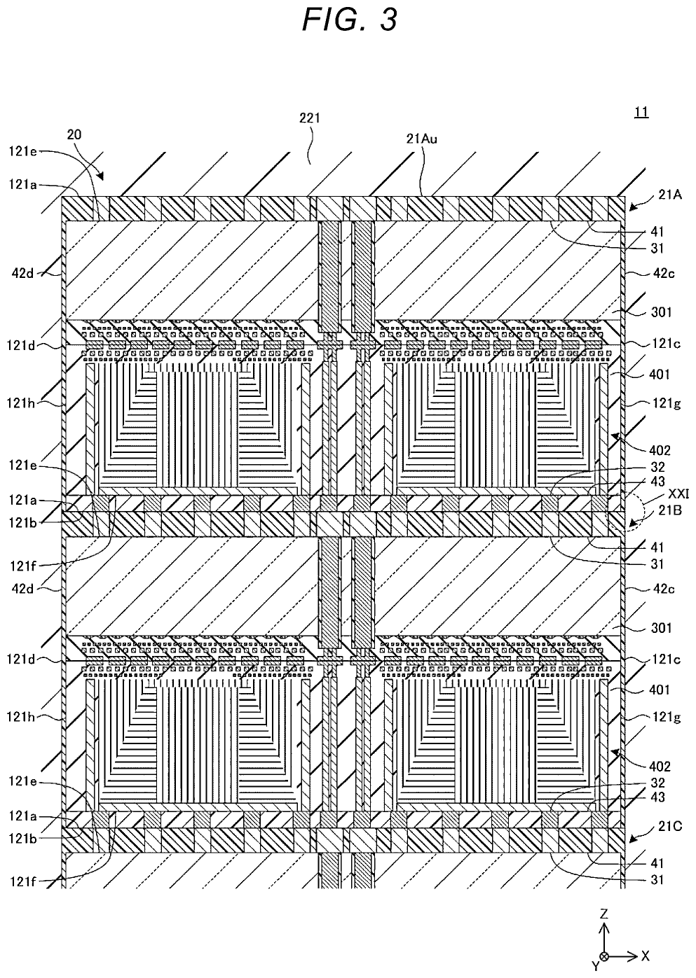

FIG. 3 is a drawing in which an upper portion of the layered body shown in FIG. 1 is enlarged. As shown in FIG. 3, two semiconductor chips 21 neighboring each other in the up-down direction are such that the pad 32 of the upper semiconductor chip 21 and the pad 31 of the lower semiconductor chip 21 are connected.

Specifically, the pad 32 of the upper semiconductor chip 21A and the pad 31 of the lower semiconductor chip 21B are joined, whereby the semiconductor chips 21A and 21B are bonded. The lower face 121b of the semiconductor chip 21A and the upper face 121a of the semiconductor chip 21B are bonding faces.

In the same way, the pad 32 of the upper semiconductor chip 21B and the pad 31 of the lower semiconductor chip 21C are joined, whereby the semiconductor chips 21B and 21C are bonded. The lower face 121b of the semiconductor chip 21B and the upper face 121a of the semiconductor chip 21C are bonding faces.

Although not shown in FIG. 3, connection of the semiconductor chips 21C and 21D is the same as the connection of the semiconductor chips 21A and 21B.

In the present embodiment, as shown in FIGS. 1 and 3, a surface roughness of the insulating film 41 on the upper face 121a of the semiconductor chip 21A positioned uppermost is less than a surface roughness of the insulating film 42 on the side face 121 of each semiconductor chip. Specifically, a degree of roughness of a surface 21Au of the insulating film 41 on the upper face 121a of the semiconductor chip 21A is less than a degree of roughness of the insulating film 42 on the side face 121 of each of the semiconductor chips 21A, 21B, 21C, and 21D. A reason for this will be described hereafter.

### Semiconductor Device Manufacturing Method

Hereafter, a method of manufacturing the storage device 11 will be described as one example of a method of manufacturing a semiconductor device according to the present embodiment.

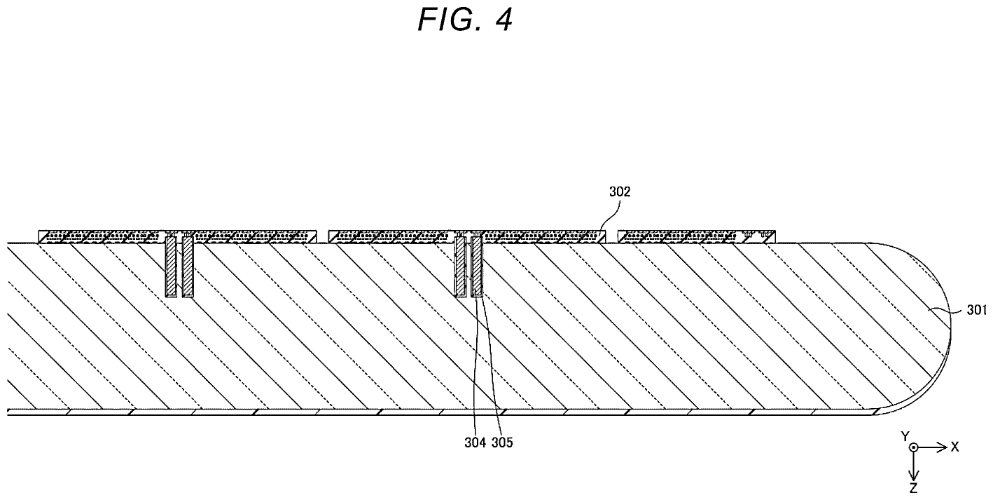

Firstly, as shown in FIG. 4, the insulating layer 302 is formed below the substrate 301. Further, the through via 304 is formed across the insulating layer 305 in the substrate 301 and the insulating layer 302.

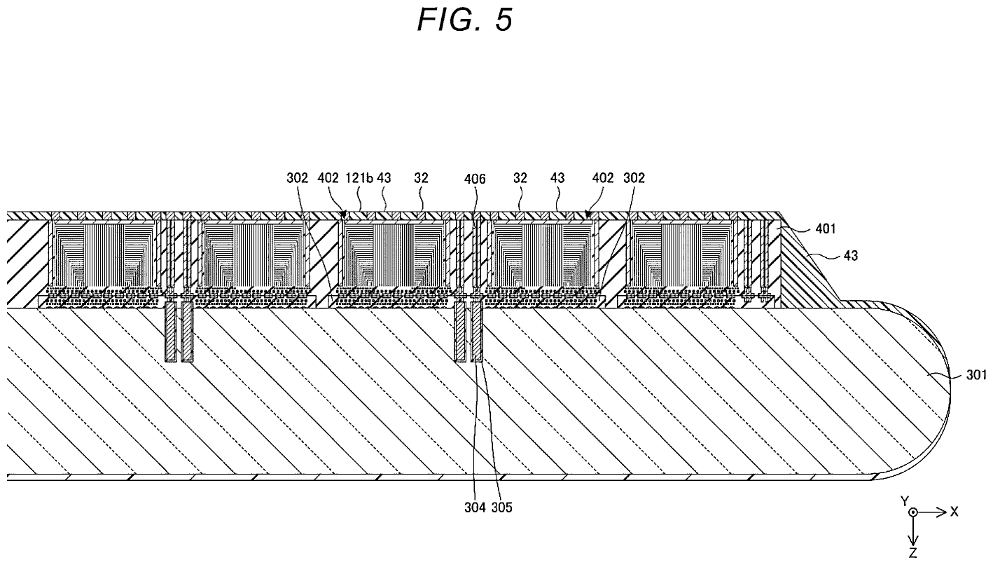

Next, as shown in FIG. 5, the memory array 402 and the insulating layer 401 are formed below the insulating layer 302.

The insulating film 43 is formed on the lower face of the insulating layer 401 using spin coating or chemical vapor deposition (CVD). The pad 32 is formed of plating or the like in an aperture formed in the insulating film 43 by a resist application, exposure, development, detachment, and the like being carried out on a lower face of the insulating film 43 using a photoengraving process (PEP). Further, the pad 32 and the lower face of the insulating film 43 are smoothed by a chemical mechanical polishing (CMP) being carried out.

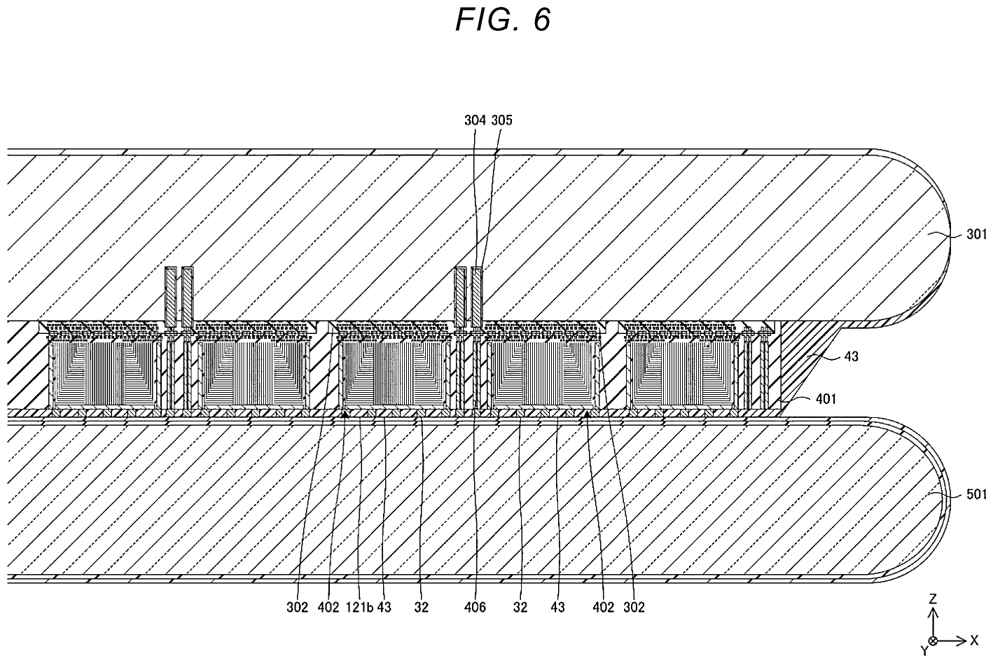

Next, as shown in FIG. 6, a support substrate 501 is bonded to the lower faces of the insulating film 43 and the pad 32.

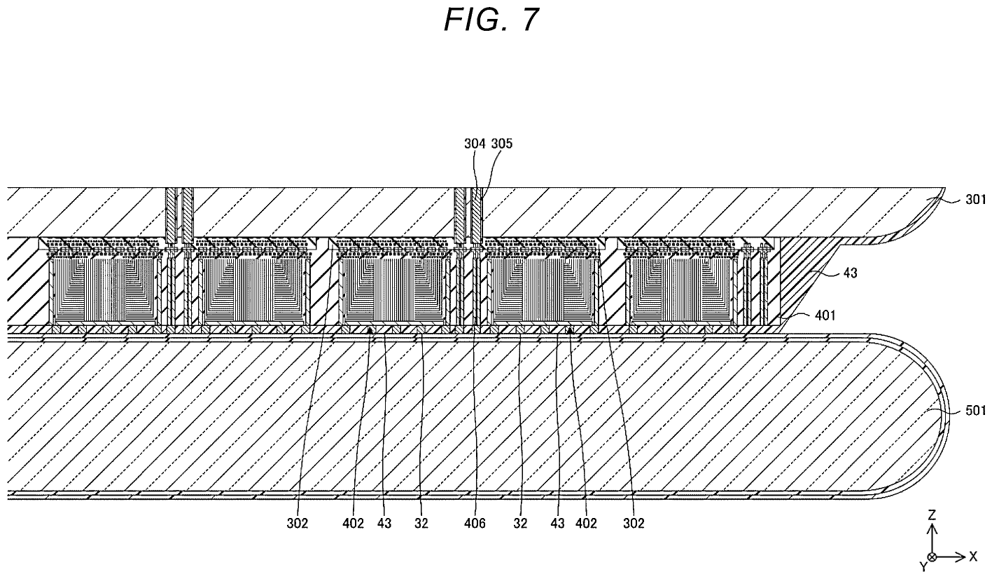

Next, for example, chemical mechanical polishing is carried out on the upper face of the substrate 301, as shown in FIG. 7. Because of this, a thickness of the substrate 301 decreases, and the through via 304 and the insulating layer 305 are exposed in the upper face of the substrate 301.

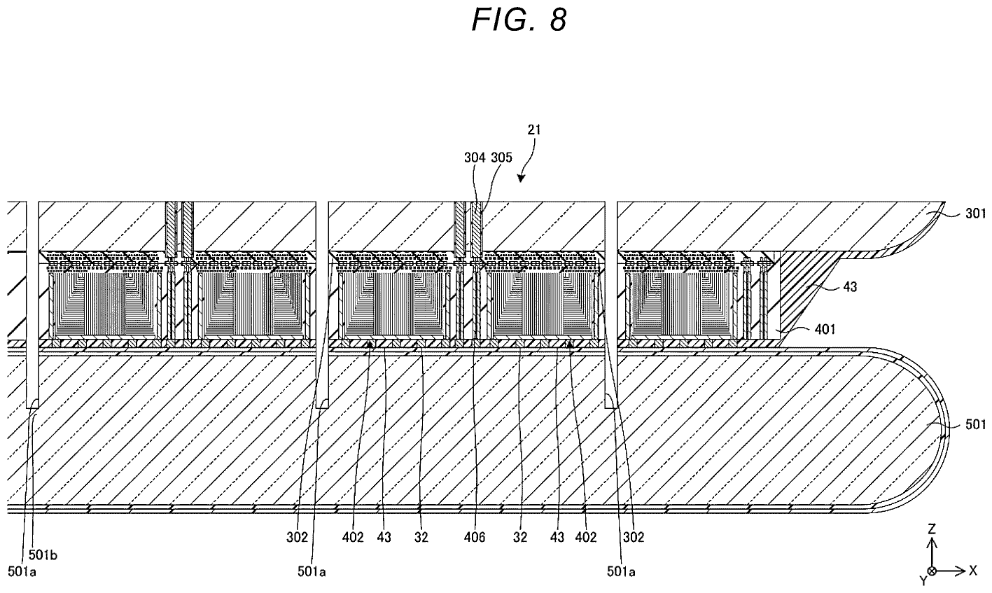

Next, for example, a groove 501a, whose bottom is downward and which extends in the Y axis direction, is formed by diced being carried out from above the substrate 301 using a dicing saw that has a first thickness, as shown in FIG. 8. Although not shown, a groove having the same form as the groove 501a is formed in the X axis direction by dicing being carried out from above the substrate 301 using the dicing saw that has the first thickness.

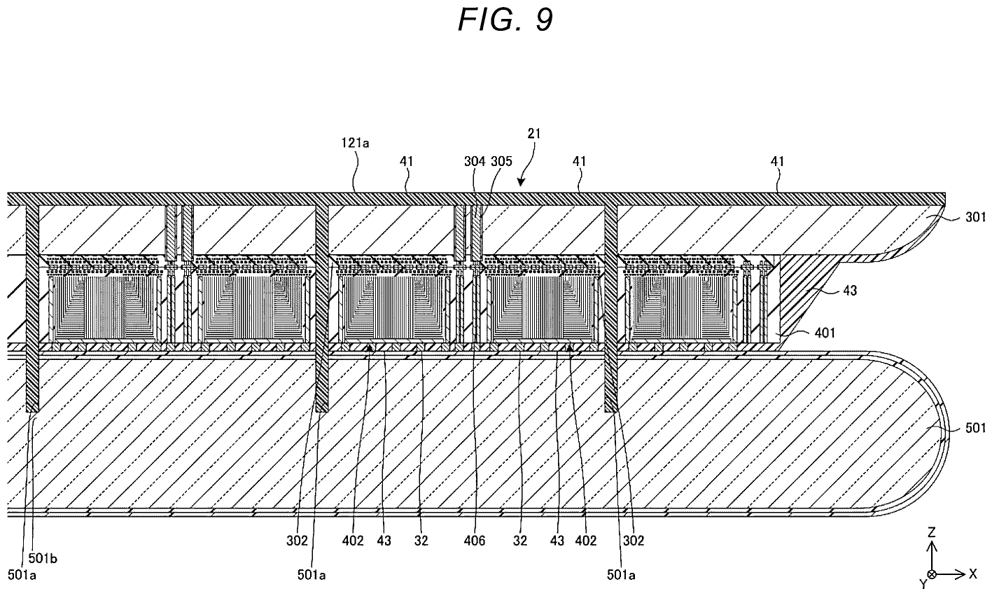

Next, as shown in FIG. 9, the insulating film 41 is formed on the upper face of the substrate 301 and in the groove 501a using spin coating or CVD.

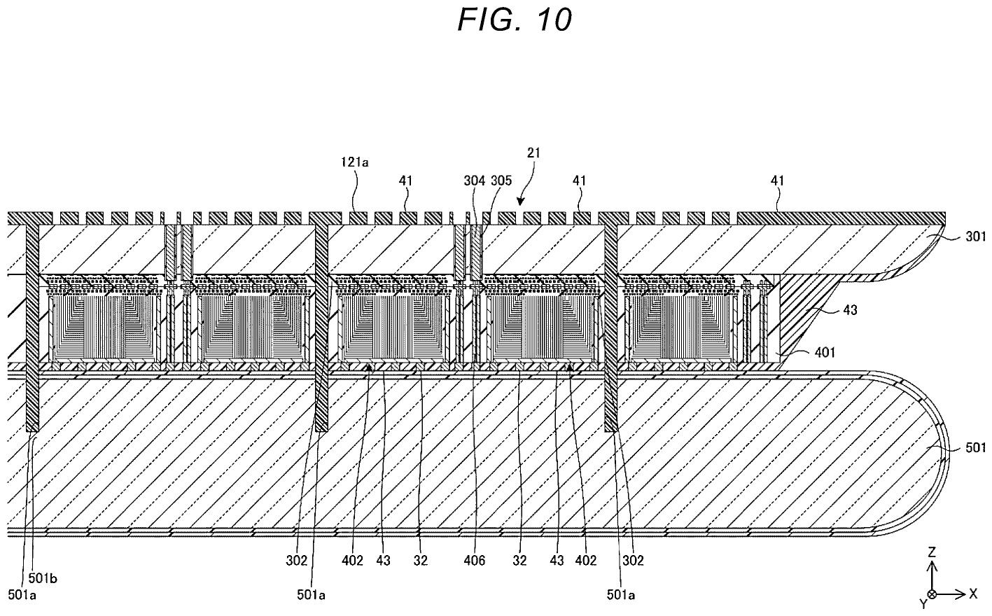

Next, as shown in FIG. 10, an aperture is formed in the insulating film 41 by a resist application, exposure, development, detachment, and the like being carried out on an upper face of the insulating film 41 using a PEP. Because of this, the through via 304 is exposed.

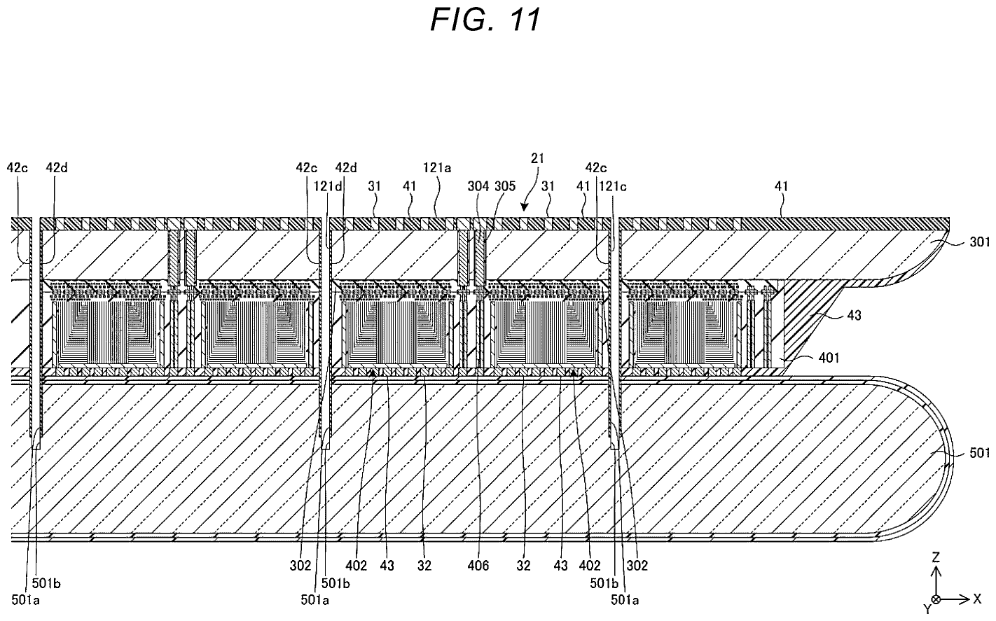

Next, as shown in FIG. 11, the pad 31 is formed of plating or the like in the aperture formed in the insulating film 41. The pad 31 and the upper face of the insulating film 41 are smoothed by chemical mechanical polishing being carried out. Further, a groove 501b having a width smaller than that of the groove 501a is formed by dicing along the groove 501a being carried out from above the substrate 301 using a dicing saw that has a second thickness smaller than the first thickness. Although not shown, a groove having the same form as the grooves 501a and 501b is formed in the X axis direction by dicing being carried out from above the substrate 301 using the dicing saw that has the second thickness. Because of this, the upper face 121a and the side faces 121c and 121d are formed.

As heretofore described, the upper face 121a is a smooth face owing to chemical mechanical polishing being carried out, but the side faces 121c and 121d are faces cut using a dicing saw. Because of this, the surface roughness of the insulating film 41 on the upper face 121a is less than the surface roughness of the insulating film 42 on the side face 121.

Also, a thickness of the insulating film 42c and a thickness of the insulating film 42d vary in accordance with an accuracy of a position in which the dicing saw that has the first thickness is inserted and an accuracy of a position in which the dicing saw that has the second thickness is inserted. The thickness of the insulating film 42c and the thickness of the insulating film 42d vary in accordance with an accuracy of the first thickness achieved by the dicing saw that has the first thickness. Also, the thickness of the insulating film 42c and the thickness of the insulating film 42d vary in accordance with an accuracy of the second thickness achieved by the dicing saw that has the second thickness.

The present embodiment is such that when comparing the thicknesses of any two insulating films 42, the thickness of one insulating film 42 is 0.5 times or more, 1.5 times or less the thickness of the other insulating film 42.

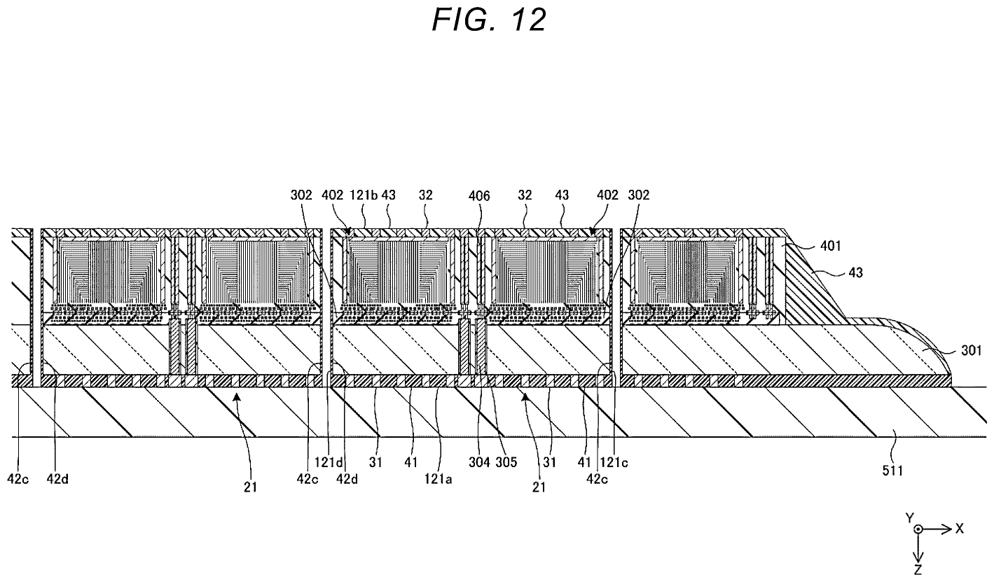

Next, as shown in FIG. 12, the substrate 301 is placed below a protective tape 511, and the support substrate 501 is removed. Because of this, the substrate 301 and the insulating layer 401 are divided among a multiple of semiconductor chips 21.

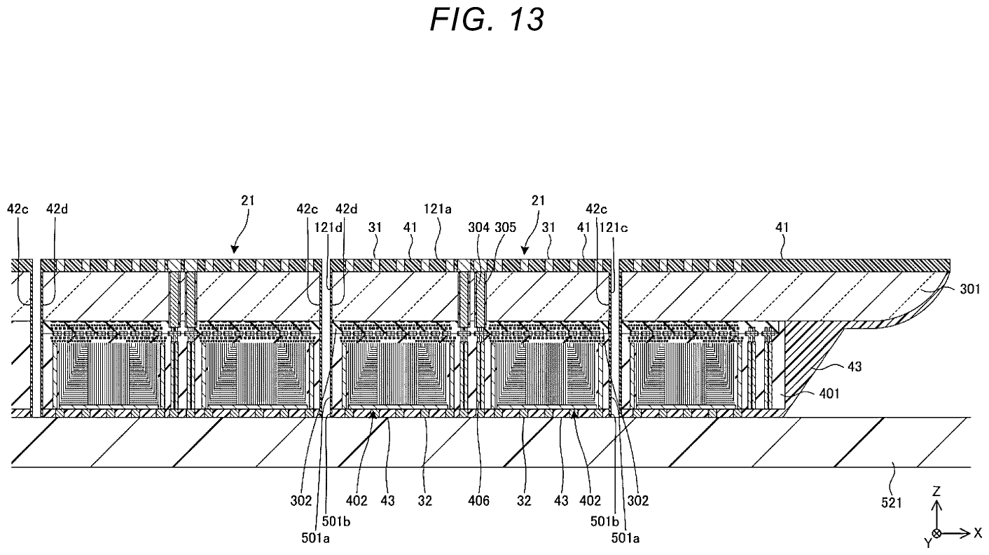

Next, as shown in FIG. 13, the multiple of semiconductor chips 21 are placed above a dicing tape 521, oriented in such a way that the insulating layer 401 is farther downward than the substrate 301.

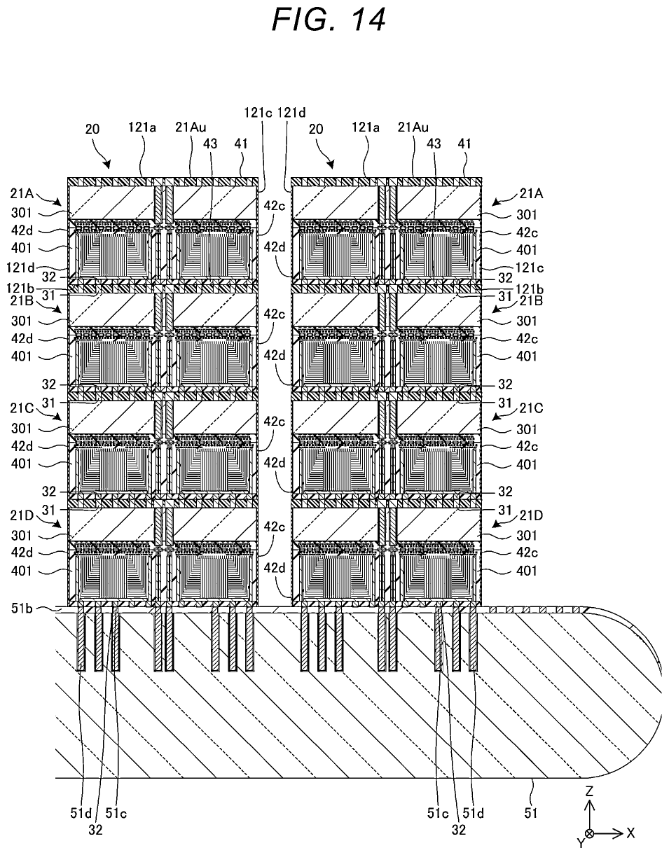

Next, as shown in FIG. 14, each of the multiple of semiconductor chips 21D is bonded to the upper face 151a of the interposer chip 51, oriented in such a way that the insulating layer 401 is farther downward than the substrate 301. At this time, the pad 51c in the insulating layer 51b and the pad 32 in the semiconductor chip 21D are joined.

The multiple of semiconductor chips 21C are bonded one-to-one from above to the multiple of semiconductor chips 21D, oriented in such a way that the insulating layer 401 is farther downward than the substrate 301. At this time, the pad 31 in the semiconductor chip 21D and the pad 32 in the semiconductor chip 21C are joined.

In the same way, the multiple of semiconductor chips 21B are bonded one-to-one from above to the multiple of semiconductor chips 21C, oriented in such a way that the insulating layer 401 is farther downward than the substrate 301. The multiple of semiconductor chips 21A are bonded one-to-one from above to the multiple of semiconductor chips 21B, oriented in such a way that the insulating layer 401 is farther downward than the substrate 301. Because of this, the multiple of layered bodies 20 are formed above the interposer chip 51.

Also, the thickness of the insulating layer 42 of the semiconductor chip 21A positioned uppermost is 0.5 times or more, 1.5 times or less the thickness of the insulating film 42 in the semiconductor chip 21D positioned lowermost.

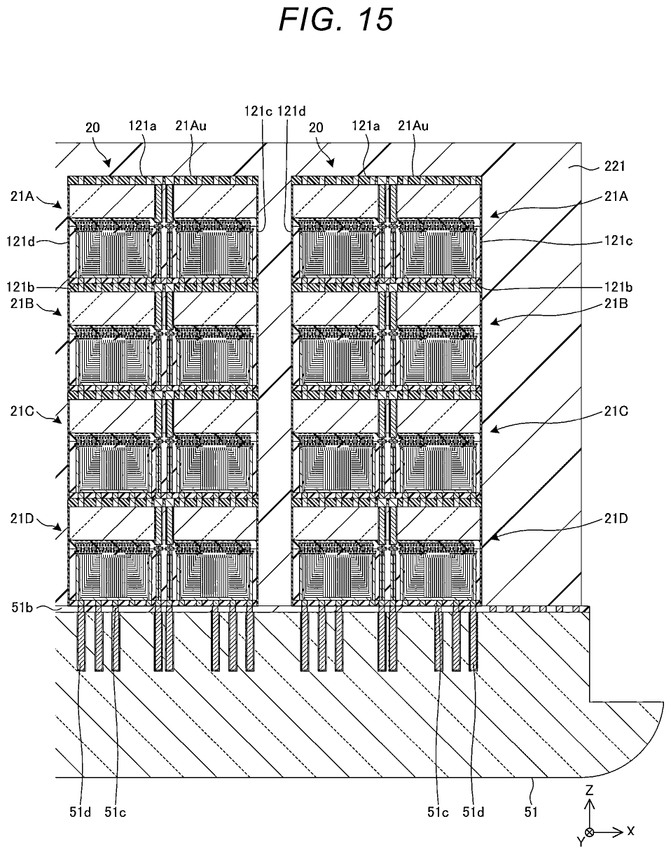

Next, as shown in FIG. 15, the sealing resin 221 is formed above the interposer chip 51 in such a way that the multiple of layered bodies 20 are covered. Also, an outer periphery of the interposer chip 51 is cut off.

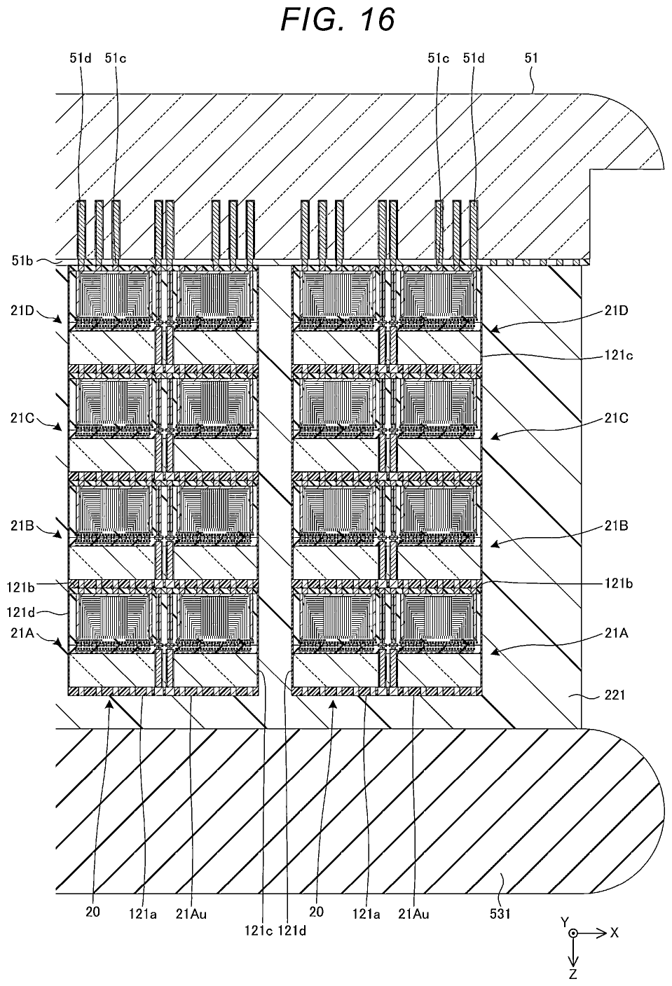

Next, as shown in FIG. 16, a support substrate 531 of a semiconductor including silicon or of glass is bonded above the sealing resin 221.

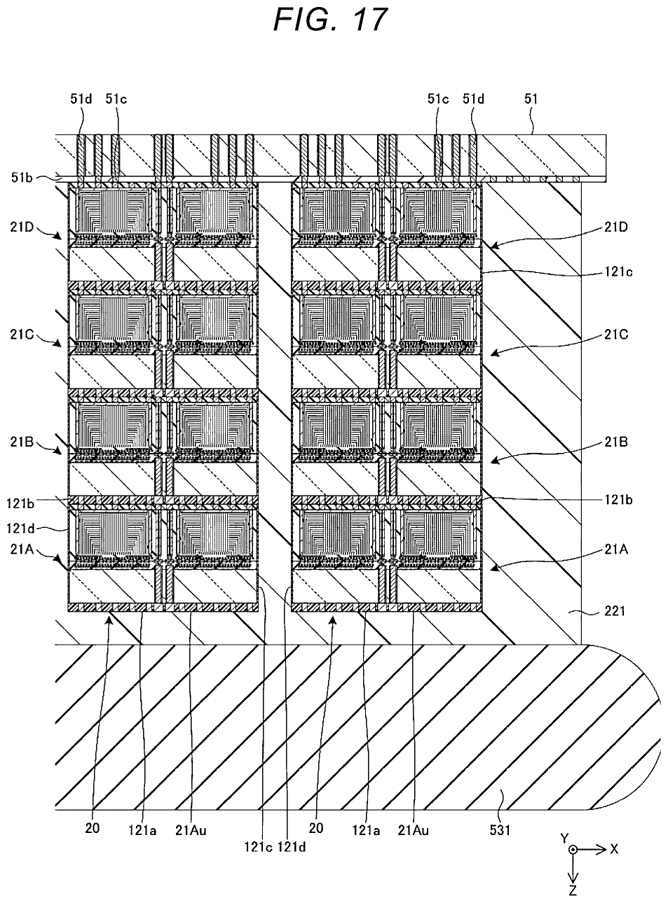

Next, for example, a chemical mechanical polishing is carried out on a lower face of the interposer chip 51, as shown in FIG. 17. Because of this, the thickness of the interposer chip 51 decreases, and the via 51d is exposed in the lower face of the interposer chip 51.

Next, the support substrate 531 is removed and, for example, the interposer chip 51 and the sealing resin 221 are cut using a dicing saw. Because of this, the multiple of layered bodies 20 bonded one each to the divided multiple of interposer chips 51 are formed.

Next, as shown in FIG. 1, the controller chip 56 is mounted face down on the interposer chip 51. The interposer chip 51 is flip-chip connected to the organic substrate 211 by the solder ball 51f being connected to the pad 211a of the organic substrate 211. Further, the sealing resin 222 is formed above the organic substrate 211 in such a way that the layered body 20 is covered.

### Advantages

When, provisionally, the insulating films 41 and 42 are not formed, adherence of the sealing resin 221 to a semiconductor substrate including silicon is low when the layered body 20 is covered by the sealing resin 221, because of which the sealing resin 221 may become detached from the substrate 301.

On the contrary, the semiconductor chip 21 is such that the insulating films 41 and 42, which have good adhesion to both the sealing resin 221 and the substrate 301, are formed on the upper face 121a and the side face 121 respectively. Because of this, the substrate 301 and the sealing resin 221 adhere well to the insulating films 41 and 42, which are provided between the substrate 301 and the sealing resin 221, because of which the sealing resin 221 can be restricted from becoming detached.

Also, when, provisionally, the insulating film 41 is not formed, an unevenness in the upper face 121a of the semiconductor chip 21 becomes larger. In the same way, when, provisionally, the insulating film 43 is not formed, an unevenness in the lower face 121b of the semiconductor chip 21 becomes larger. In these cases, when two semiconductor chips 21 are bonded, an opening such that a gap is formed between the upper face 121a and the lower face 121b appears in a place near the side face 121.

On the contrary, the semiconductor chip 21 is such that the insulating films 41 and 43 are formed on the upper face 121a and the lower face 121b respectively. Because of this, unevenness in the upper face 121a and the lower face 121b can be reduced in size, meaning that an opening can be restricted from appearing when two semiconductor chips 21 are bonded.

### Second Embodiment

A storage device 12 (one example of a “semiconductor device”) according to a second embodiment will be described. From the second embodiment onward, a description of matters the same as in the first embodiment will be omitted, and only differing points will be described. In particular, identical operational advantages resulting from identical configurations will not be referred to sequentially in each embodiment.

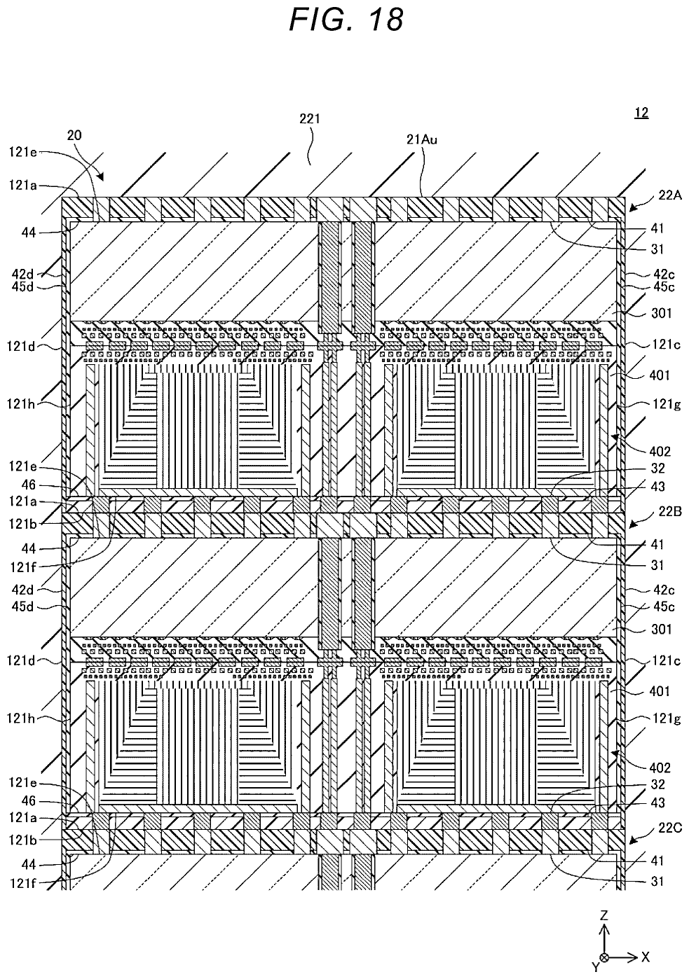

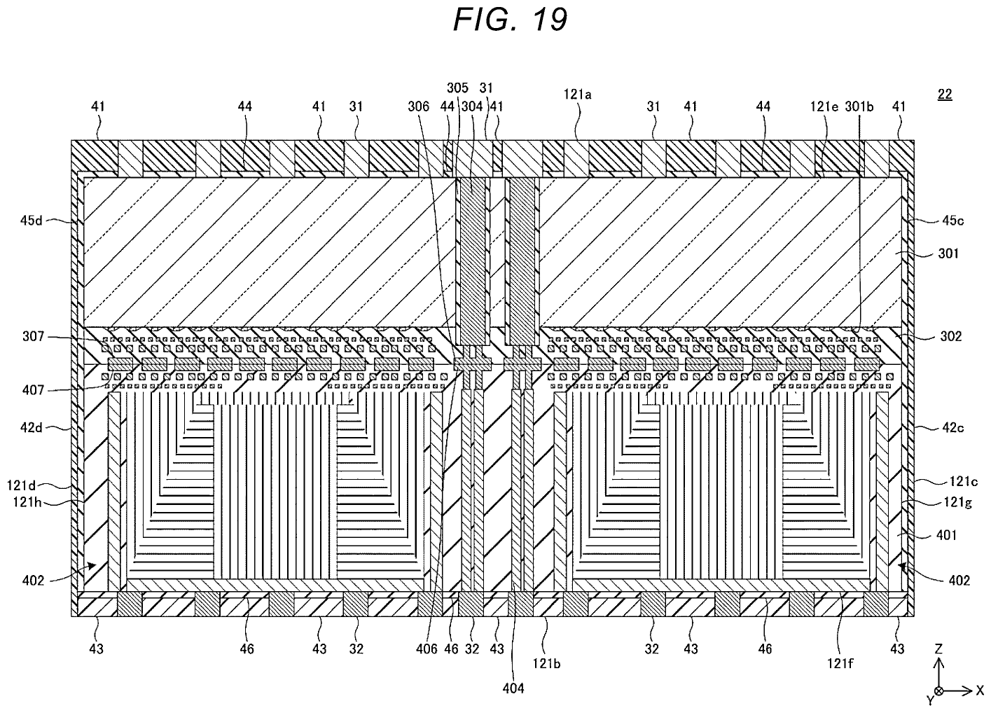

FIG. 18 is a drawing in which an upper portion of a layered body according to the second embodiment is enlarged. FIG. 19 is a sectional schematic view illustrating an example of a structure of a semiconductor chip according to the second embodiment, and is a sectional view parallel to the XY plane.

As shown in FIGS. 18 and 19, the layered body 20 in the storage device 12, when compared with the layered body 20 in the storage device 11 (refer to FIGS. 1 and 3), includes semiconductor chips 22A, 22B, 22C, and 22D (not shown) instead of the semiconductor chips 21A, 21B, 21C, and 21D. Hereafter, each of the semiconductor chips 22A, 22B, 22C, and 22D may be called a semiconductor chip 22.

The semiconductor chip 22 is such that the insulating film 41 is formed on an insulating film 44 (one example of a “fourth insulating film”). The insulating films 42c and 42d are formed on insulating films 45c (one example of a “fifth insulating film”) and 45d (one example of a “fifth insulating film”) respectively. Hereafter, each of the insulating films 45c and 45d may be called an insulating film 45.

The insulating film 43 is formed on an insulating film 46 (one example of a “sixth insulating film”). The insulating film 45 is connected to the insulating films 44 and 46.

Specifically, the insulating film 44 encloses the pad 31, and is formed on the base face 121e. The insulating films 45c and 45d are formed on the base faces 121g and 121h respectively. After the insulating films 44 and 45 are formed, the insulating films 41 and 42 are formed on the insulating film 44 and the insulating film 45d respectively.

The insulating film 46 encloses the pad 32, and is formed on the base face 121f. After the insulating film 46 is formed, the insulating film 43 is formed on the insulating film 46.

In the present embodiment, the insulating films 44 and 45 have the same composition. The insulating films 44 and 45 include, for example, silicon. Specifically, the insulating films 44 and 45 include silicon and oxygen or silicon and nitrogen. More specifically, the insulating films 44 and 45 are films of SiO, SiN, or SiCN. The insulating films 44 and 45, not being limited to the aforementioned compositions, may have another composition. Also, the composition of the insulating film 44 and the composition of the insulating film 45 may differ.

The insulating film 46 may have the same composition as the insulating films 44 and 45. Specifically, the insulating films 44 and 45 are films of SiO, SiN, or SiCN. The insulating film 46, not being limited to the aforementioned compositions, may have another composition. Also, the composition of the insulating film 46 and the compositions of the insulating films 44 and 45 may differ.

In this way, adhesion of the insulating films 41 and 42 can be effectively increased using a configuration such that the insulating films 44 and 45 are provided as bases of the insulating films 41 and 42 respectively.

In the same way, adhesion of the insulating film 43 can be effectively increased using a configuration such that the insulating film 46 is provided as a base of the insulating film 43.

### Third Embodiment

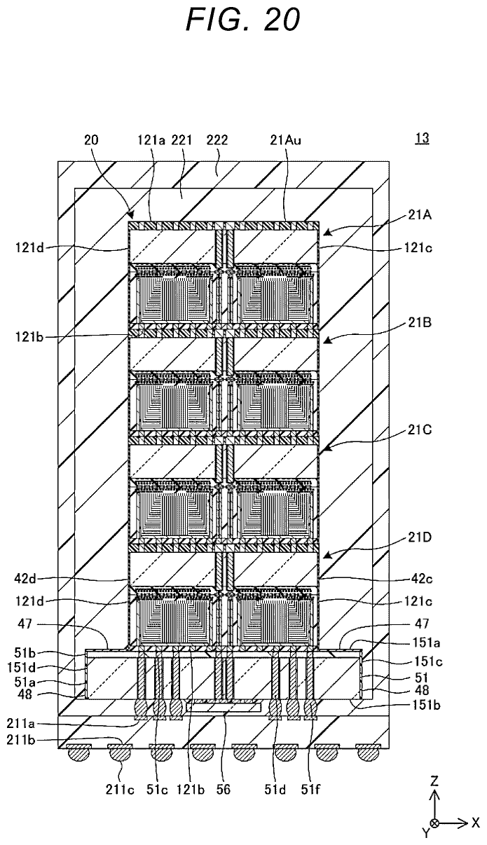

A storage device 13 (one example of a “semiconductor device”) according to a third embodiment will be described. FIG. 20 is a sectional schematic view illustrating an example of a structure of a storage device according to the third embodiment, and is a sectional view parallel to the XY plane.

As shown in FIG. 20, the storage device 13 is such that the lower face 121b of the semiconductor chip 21D positioned lowermost (one example of a “lowermost semiconductor chip) is connected to the upper face 151a (one example of a “second upper face”) of the interposer chip 51. Also, an insulating film 47 (one example of a “seventh insulating film”) connected to each of the insulating films 42c and 42d is formed on the upper face 151a in end portions of the side faces 121c and 121d of the semiconductor chip 21D.

An insulating film 48 (one example of an “eighth insulating film”) connected to to the insulating film 47 in an end portion of the upper face 151a is formed on the side faces 151c (one example of a “second side face”) and 151d (one example of a “second side face”) of the interposer chip 51.

The sealing resin 221 covers the layered body 20, the insulating film 47, and the insulating film 48. That is, the side faces 151c and 151d of the interposer chip 51 are also covered by the sealing resin 221.

The storage device 13 is such that the insulating films 47 and 48, which have good adhesion to the sealing resin 221, the semiconductor layer 51a, and the insulating layer 51b, are formed on the upper face 151a and the side face 151 respectively of the interposer chip 51. Because of this, the semiconductor layer 51a or the insulating layer 51b and the sealing resin 221 adhere well to the insulating films 47 and 48, which are provided between the semiconductor layer 51a or the insulating layer 51b and the sealing resin 221, because of which the sealing resin 221 can be restricted from becoming detached.

a. In the embodiments, a configuration such that the insulating film 43 has the same composition as the insulating film 41 is described, but this is not limiting. A configuration such that the insulating film 43 has a composition differing from that of the insulating film 41 may also be adopted.

b. In the embodiments, a configuration such that the insulating film 42 has the same composition as the insulating film 41 is described, but this is not limiting. A configuration such that the insulating film 42 has a composition differing from that of the insulating film 41 may also be adopted.

c. In the embodiments, a configuration such that the insulating film 43 is formed on the lower face 121b of the semiconductor chip 21 is described, but this is not limiting. A configuration such that the pad 32 is formed on the lower face 121b of the semiconductor chip 21 but the insulating film 43 is not formed may also be adopted.

d. In the embodiments, a configuration such that the insulating film 42 is formed on four side faces 121 of the semiconductor chip 21 is described, but this is not limiting. A configuration such that the insulating film 42 is formed on one, two, or three side faces 121 may also be adopted.

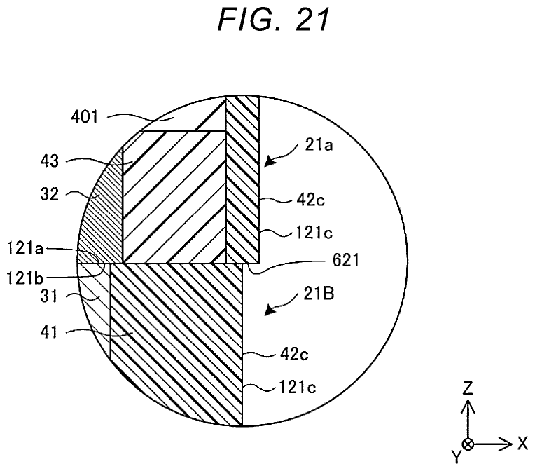

e. FIG. 21 is an enlargement of a portion of FIG. 3 enclosed by dotted lines. In the embodiments, two semiconductor chips 21 neighboring each other in the up-down direction are such that the insulating film 42c formed on the side face 121c of the upper semiconductor chip 21 and the insulating film 42c formed on the side face 121c of the lower semiconductor chip 21 are smoothly connected. The same applies to other side faces, such as the side face 121d.

However, a step 621 may be formed in a portion in which two semiconductor chips 21 are connected, as shown in FIG. 21. The step 621 is caused by, for example, a deviation in arrangement when the two semiconductor chips 21 are stacked one on the other, or variation in the sizes of the semiconductor chips 21 caused by cutting.

For example, being caused by a deviation in arrangement means that when the insulating film 42c of the side face 121c of the upper semiconductor chip 21 (for example, the semiconductor chip 21A) deviates farther in the X axis + direction than the insulating film 42c of the side face 121c of the lower semiconductor chip 21 (for example, the semiconductor chip 21B), the insulating film 42d of the side face 121d of the upper semiconductor chip 21A may deviate farther in the X axis + direction than the insulating film 42d of the side face 121d of the lower semiconductor chip 21B. Also, with regard to the Y axis direction too, the insulating film 42 of the side face 121 of the upper semiconductor chip 21 may deviate farther in one direction than the insulating film 42 of the side face 121 of the lower semiconductor chip 21.

Being caused by a variation in sizes means that when, for example, the size of the upper semiconductor chip 21 is greater than the size of the lower semiconductor chip 21, the insulating film 42 of the side face 121 of the upper semiconductor chip 21 protrudes farther to the outer side than the insulating film 42 of the side face 121 of the lower semiconductor chip 21. When the size of the lower semiconductor chip 21 is greater than the size of the upper semiconductor chip 21, the insulating film 42 of the side face 121 of the lower semiconductor chip 21 protrudes farther to the outer side than the insulating film 42 of the side face 121 of the upper semiconductor chip 21.

For these kinds of reason, the insulating films 42 do not connect smoothly in a portion in which two semiconductor chips 21 are connected, and the step 621 is formed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a plurality of semiconductor chips stacked on top of one another, wherein
each of the plurality of semiconductor chips includes a first upper face on which a first pad and a first insulating film enclosing the first pad are formed,
a first lower face on which a second pad is formed, and
at least one first side face, connected to the first insulating film in an end portion of the first upper face, on which a second insulating film is formed, the second insulating film and the second insulating film having the same composition, and
the second pad of an upper one of the semiconductor chips and the first pad of a lower one of the semiconductor chips are connected.

2. The semiconductor device according to claim 1, wherein a surface roughness of the first insulating film on the first upper face of an uppermost one of the semiconductor chips is less than a surface roughness of the second insulating film on the first side face of the semiconductor chips.

3. The semiconductor device according to claim 1, wherein a third insulating film that encloses the second pad is further formed on the first lower face.

4. The semiconductor device according to claim 3, wherein the second insulating film is connected to the third insulating film in an end portion of the first lower face.

5. The semiconductor device according to claim 3, wherein the third insulating film and the first insulating film have the same composition.

6. The semiconductor device according to claim 3, wherein the third insulating film and the first insulating film have different compositions.

7. The semiconductor device according to claim 1, wherein the first insulating film and the second insulating film are formed together.

8. The semiconductor device according to claim 1, wherein a thickness of the second insulating film of an uppermost one of the semiconductor chips is 0.5 times or more, 1.5 times or less a thickness of the second insulating film of a lowermost one of the semiconductor chips.

9. The semiconductor device according to claim 1, wherein the first insulating film is formed of a resin including a polymer.

10. The semiconductor device according to claim 3, wherein the third insulating film is formed of a resin including a polymer.

11. The semiconductor device according to claim 1, wherein the first insulating film is formed on a fourth insulating film that encloses the first pad and includes silicon, and the second insulating film is formed on a fifth insulating film that is connected to the fourth insulating film and has a composition the same as that of the fourth insulating film.

12. The semiconductor device according to claim 3, wherein the third insulating film is formed on sixth insulating film that encloses the second pad and includes silicon.

13. The semiconductor device according to claim 1, further comprising an interposer chip that includes a second upper face, to which the first lower face of a lowermost semiconductor chip, which is the semiconductor chip positioned lowermost, is connected and on which a seventh insulating film connected to the second insulating film in an end portion of the first side face of the lowermost semiconductor chip is formed, and at least one second side face on which an eighth insulating film connected to the seventh insulating film in an end portion of the second upper face is formed.

14. A semiconductor device, comprising:
a plurality of semiconductor chips stacked on top of one another, wherein
each of the semiconductor chips includes a first upper face on which a first pad and a first insulating film enclosing the first pad are formed,
a first lower face on which a second pad is formed, and
at least one first side face, connected to the first insulating film in an end portion of the first upper face, on which a second insulating film is formed,
the second pad of an upper one of the semiconductor chips and the first pad of a lower one of the semiconductor chips are connected, and
a surface roughness of the first insulating film on the first upper face of an uppermost one of the semiconductor chips is less than a surface roughness of the second insulating film on the first side face of the semiconductor chips.

15. The semiconductor device according to claim 14, wherein a third insulating film that encloses the second pad is further formed on the first lower face.

16. The semiconductor device according to claim 14, wherein a thickness of the second insulating film of the uppermost semiconductor chip is 0.5 times or more, 1.5 times or less a thickness of the second insulating film of a lowermost one of the semiconductor chips.
